(19) United States
(12) Patent Application Publication
(10) Pub. No.: US 2026/0287998 A1
(43) Pub. Date: Sep. 24, 2026

(54) SUBSTRATE PROCESSING METHOD AND SUBSTRATE PROCESSING DEVICE

(71) Applicant: Kioxia Corporation, Tokyo (JP)

(72) Inventors: Nozomi SAITO, Yokohama (JP); Kaori UMEZAWA, Fujisawa (JP); Kosuke TAKAI, Yokohama (JP)

(73) Assignee: Kioxia Corporation, Tokyo (JP)

(21) Appl. No.: 19/235,743

(22) Filed: Jun. 12, 2025

(30) Foreign Application Priority Data
Mar. 21, 2025 (JP) 2025-046409

(51) Int. Cl. G03F 1/82; B05B 1/02; B08B 3/10; B08B 7/00; B08B 13/00

(52) U.S. Cl. CPC G03F 1/82; B05B 1/02; B08B 3/10; B08B 7/0014; B08B 7/0092; B08B 13/00

(57) ABSTRACT

According to one embodiment, a substrate processing method includes forming a liquid film in a second region of a substrate having, on a first surface, a first region and the second region provided inside the first region by feeding a first liquid to the second region, solidifying the liquid film, and feeding a second liquid to the first region of the substrate. The first region and the second region are different in magnitude relationship between a dispersive component and a polar component in surface free energy, and a magnitude relationship between a dispersive component and a polar component in surface free energy of the first liquid is equal to the magnitude relationship in the second region.

### CROSS-REFERENCE TO RELATED APPLICATIONS

This application is based upon and claims the benefit of Japanese Patent Application No. 2025-046409, filed on March 21, 2025; the entire contents of which are incorporated herein by reference.

### FIELD

Embodiments described herein relate generally to a substrate processing method and a substrate processing device.

### BACKGROUND

A liquid such as a cleaning liquid is sometimes fed to a substrate surface to remove an impurity attached to the substrate surface.

For example, if a residual liquid component is present on a substrate surface of a photomask, a growing defect that grows as exposure is repeated sometimes occurs on the substrate surface.

### BRIEF DESCRIPTION OF THE DRAWINGS

FIG. 1 is a diagram illustrating an example of a configuration of a photomask according to a first embodiment;

FIGS. 2A and 2B are diagrams for explaining a surface state of a substrate to be subjected to restoration processing according to the first embodiment;

FIG. 3 is a flowchart illustrating an example of a flow of the restoration processing according to the first embodiment;

FIG. 4 is a diagram illustrating an example of a configuration of a substrate processing device according to the first embodiment;

FIGS. 5Aa to 5Bb illustrate part of a flow of substrate processing according to the first embodiment in order;

FIGS. 6Ca to 6Db illustrate part of the flow of the substrate processing according to the first embodiment in order;

FIG. 7 is a diagram illustrating an example of a configuration of a nozzle according to a first modification of the first embodiment;

FIGS. 8A and 8B illustrate part of a flow of substrate processing according to the first modification of the first embodiment in order;

FIG. 9 is a diagram illustrating an example of a configuration of a nozzle according to a second modification of the first embodiment;

FIGS. 10A and 10B are diagrams illustrating an example of a configuration of a nozzle according to a third modification of the first embodiment;

FIGS. 11A and 11B illustrate part of a flow of substrate processing according to the third modification of the first embodiment in order;

FIG. 12 is a diagram illustrating an example of a configuration of a nozzle according to a second embodiment;

FIGS. 13A and 13B illustrate part of a flow of substrate processing according to the second embodiment in order; and

FIG. 14 is a diagram illustrating an example of a configuration of a nozzle according to a modification of the second embodiment.

### DETAILED DESCRIPTION

In general, according to one embodiment, a substrate processing method includes a first process of forming a liquid film in a second region of a substrate having, on a first surface, a first region and the second region provided inside the first region by feeding a first liquid to the second region, a second process of solidifying the liquid film, and a third process of feeding a second liquid different from the first liquid to the first region of the substrate on which the liquid film has been solidified. The first region and the second region are different in magnitude relationship between a dispersive component and a polar component in surface free energy, and a magnitude relationship between a dispersive component and a polar component in surface free energy of the first liquid is equal to the magnitude relationship in the second region.

Exemplary embodiments of a substrate processing method and a substrate processing device will be explained below in detail with reference to the accompanying drawings. The present invention is not limited to the following embodiments.

### First Embodiment

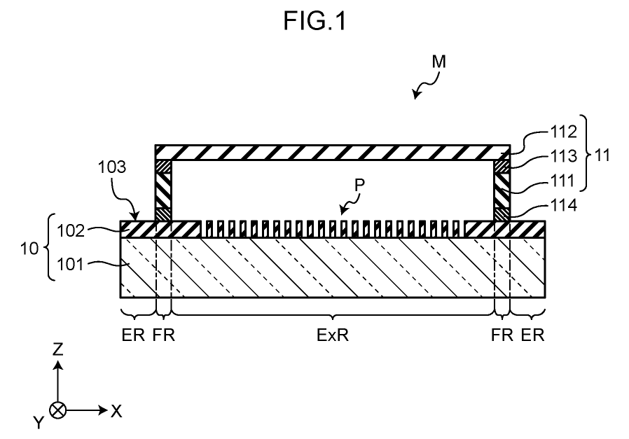

A first embodiment is described below with reference to FIGS. 1 to 6Db. In the first embodiment below, a configuration for suppressing occurrence of a growing defect on a photomask is described by taking, as an example, a case where a used photomask is cleaned.

### Outline of Photomask Cleaning

FIG. 1 is a diagram illustrating an example of a configuration of a photomask M according to the first embodiment.

As illustrated in FIG. 1, the photomask M includes a substrate 10 and a pellicle 11 bonded to the substrate 10.

Note that in the present specification, a direction in which a surface of the substrate 10 to which the pellicle 11 is bonded faces is referred to as an upward direction, a direction in which an opposite surface faces is referred to as a downward direction, and an up-down direction of the substrate 10 is referred to as a Z direction. Directions orthogonal to the Z direction are referred to as an X direction and a Y direction. The X direction and the Y direction are directions along the surface of the substrate 10, and the X direction and the Y direction are orthogonal to each other. A side to which an arrow of each axis points is referred to as a positive side, and an opposite side is referred to as a negative side.

The substrate 10 includes a quartz substrate 101 and a light shielding film 102 provided on the quartz substrate 101. The quartz substrate 101 is made of quartz glass or the like. The light shielding film 102 is a film having lower exposure light transmittance than the quartz substrate 101. The light shielding film 102 contains, for example, chromium.

An upper surface 103 serving as a first surface of the substrate 10 is provided with a pattern P of the light shielding film 102, and has an exposure region ExR that is exposed to light during exposure using the photomask M and an outer edge region ER that is entirely covered with the light shielding film 102. According to layout of the pattern P, the pattern P includes a portion covered with the light shielding film 102 and a portion where the quartz substrate 101 is exposed. The exposure region ExR including the pattern P is located in a central region of the upper surface 103. The pattern P is provided in a central portion of the exposure region ExR, and an outer edge portion of the exposure region ExR is substantially entirely covered with the light shielding film 102. The outer edge region ER is located outside the exposure region ExR. Furthermore, a frame region FR to which the pellicle 11 for protecting the pattern P from a foreign substance is bonded is provided between the exposure region ExR and the outer edge region ER. The frame region FR has a frame shape, and a width thereof is, for example, 2 mm.

The pellicle 11 includes a pellicle frame 111 molded in a frame shape, a pellicle film 112, and a film adhesive 113 that bonds an upper surface of the pellicle frame 111 and the pellicle film 112 to each other. A mask adhesive 114 is applied to a lower end portion of the pellicle frame 111. The pellicle frame 111 is pasted to the frame region FR of the substrate 10 with the use of the mask adhesive 114. The mask adhesive 114 contains an organic substance such as a styrene-ethylene-butylene-styrene (SEBS) resin or an acrylic resin.

Even in a case where the pellicle 11 is bonded to the substrate 10, using the photomask M for a certain period in a lithography process sometimes causes a growing defect in the exposure region ExR. The growing defect occurs when a sulfate ion remaining on the substrate after cleaning of the photomask M, an environmental-origin ammonium ion, and the like bond and aggregate. The growing defect locally lowers exposure light transmittance of the mask and is transferred as a defect onto a wafer.

Therefore, in a case where the growing defect occurs in the exposure region ExR, restoration processing of peeling the pellicle 11 off from the substrate 10, removing the growing defect, and then bonding the pellicle 11 to the substrate 10 again is performed.

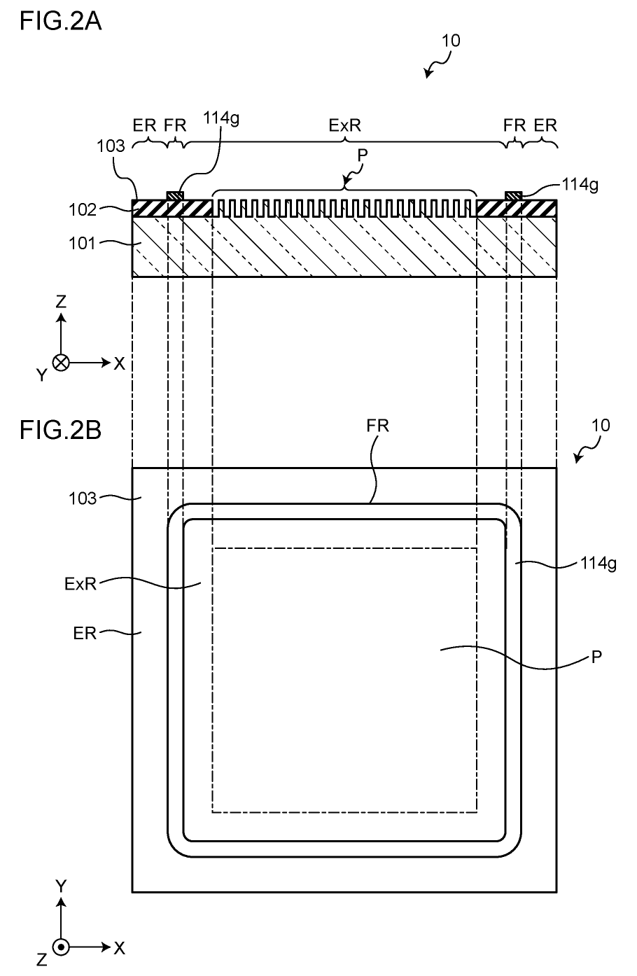

FIGS. 2A and 2B are diagrams for explaining a surface state of the substrate 10 to be subjected to restoration processing according to the first embodiment. More specifically, FIG. 2A is a XZ cross-sectional view of the substrate 10, and FIG. 2B is a top view of the substrate 10 viewed from the positive side of the Z direction.

As described above, the pellicle 11 is bonded to the frame region FR of the substrate 10 with the use of the mask adhesive 114. Accordingly, a component of the mask adhesive 114 sometimes remains on a portion where the pellicle 11 was bonded after the pellicle 11 is peeled off from the frame region FR. Hereinafter, the component of the mask adhesive 114 that remains in the frame region FR is sometimes referred to as an adhesive residue 114g.

As illustrated in FIGS. 2A and 2B, the adhesive residue 114g is present in a part or whole of the frame region FR on the upper surface 103 of the substrate 10.

The frame region FR is an example of a first region, the exposure region ExR is an example of a second region, and the outer edge region ER is an example of a third region.

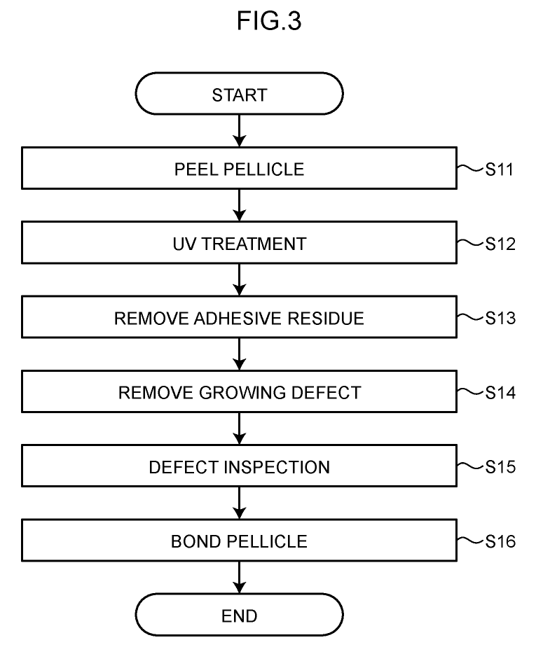

FIG. 3 is a flowchart illustrating an example of a flow of the restoration processing according to the first embodiment.

In the restoration processing of the photomask M, first, the pellicle 11 is peeled off from the substrate 10 on which a growing defect has occurred (S11). The pellicle 11 is peeled, for example, by peeling the pellicle frame from the substrate by using a predetermined peeling device. To promote the peeling, the substrate 10 is heated to a predetermined temperature.

In the restoration processing of the photomask M, the adhesive residue 114g is removed before the growing defect is removed. To remove the adhesive residue 114g, the upper surface 103 of the substrate 10 including the exposure region ExR, the frame region FR, and the outer edge region ER is ultraviolet (UV) treated (S12). This is to adjust a surface state of the upper surface 103. Note that the UV treatment is performed to such an extent that the adhesive residue 114g attached to the frame region FR is not removed.

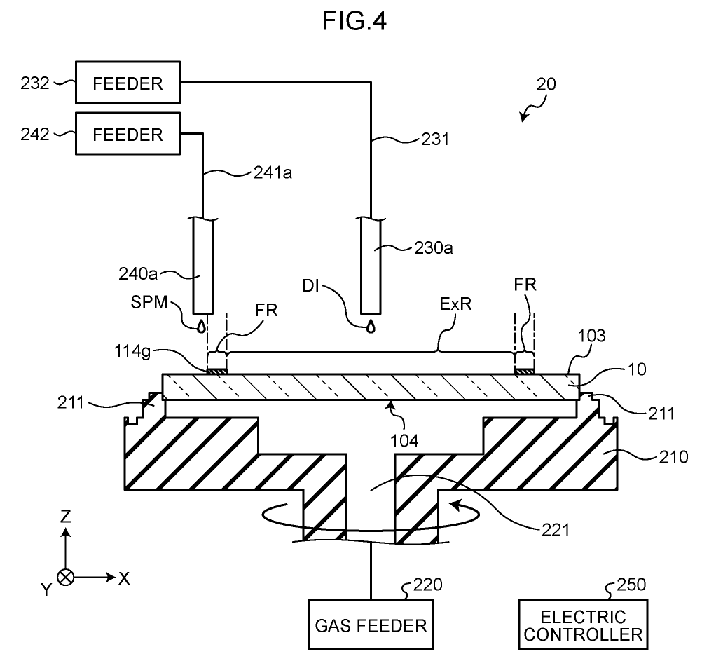

After the above UV treatment, a process for removing the adhesive residue (S13) is performed. The process for removing the adhesive residue is performed in a substrate processing device according to the present embodiment, which will be described later with reference to FIG. 4.

After the adhesive residue is removed from the frame region FR, a process for removing the growing defect is performed (S14). The process for removing the growing defect is performed, for example, by a device different from the substrate processing device used in S12.

After it has been confirmed by a defect inspection device that the growing defect has been removed (S15), the pellicle 11 is bonded onto the substrate 10 (S16). The restoration processing of the photomask M thus ends. The photomask M thus restored is shipped again after final inspection.

### Example of Configuration of Substrate Processing Device

FIG. 4 is a diagram illustrating an example of a configuration of a substrate processing device 20 according to the first embodiment.

As illustrated in FIG. 4, the substrate processing device 20 includes a stage 210, a gas feeder 220, a nozzle 230a, a nozzle 240a, and an electric controller 250.

The stage 210 has a flat plate shape and is configured such that the substrate 10 can be placed thereon. The stage 210 has on an outer edge portion thereof, a plurality of support pins 211 that can support the substrate 10. The plurality of support pins 211 support the substrate 10 from below, and thus the substrate 10 is placed on the support pins 211.

The stage 210 is rotatable along an XY plane. When the stage 210 rotates along the XY plane, the substrate 10 placed on the stage 210 also rotates along the XY plane. When the substrate 10 rotates, centrifugal force is generated, which allows a liquid fed to the upper surface 103 of the substrate 10 to move toward an outside of the substrate 10, as described later.

The nozzle 230a is located above the stage 210 so as to face the exposure region ExR of the substrate 10, and is capable of feeding pure water DI as a first liquid to the exposure region ExR. In the present specification, the pure water DI is high-purity water called de-ionized water (DIW) from which an impurity has been removed. The pure water DI is an example of the first liquid. Note that a freezing point of the pure water DI is approximately 0°C.

A feeder 232 is connected to an end portion of the nozzle 230a opposite to a side facing the substrate 10 by a pipe 231. The feeder 232 feeds the pure water DI on the basis of an instruction from the electric controller 250. The pure water DI fed from the feeder 232 is ejected from a leading end portion of the nozzle 230a toward the exposure region ExR through a pipe (not illustrated) passing through the nozzle 230a.

The nozzle 240a is located above the stage 210 so as to face the substrate 10, and is capable of feeding, as a second liquid, a cleaning liquid SPM (sulfuric acid hydrogen peroxide mixture) in which sulfuric acid and hydrogen peroxide solution are mixed to the frame region FR. Specifically, the nozzle 240a is located above the stage 210 so as to face a position slightly outward of the frame region FR of the substrate 10. The cleaning liquid SPM that has been ejected from the nozzle 240a and landed on the upper surface 103 of the substrate 10 spreads slightly inward from a position directly below the nozzle 240a. The cleaning liquid SPM is thus fed to the frame region FR.

The position slightly outward of the frame region FR of the substrate 10 is, for example, an end portion of the upper surface 103 of the substrate 10. In a case where the nozzle 240a is located so as to face the position slightly outward of the frame region FR of the substrate 10, the cleaning liquid SPM ejected from the nozzle 240a can be made less likely to enter the exposure region ExR beyond the frame region FR. That is, the pattern P provided in the exposure region ExR can be made less likely to be exposed to the cleaning liquid SPM.

The cleaning liquid SPM contains a sulfate ion. The cleaning liquid SPM dissolves the adhesive residue 114g. A freezing point of the cleaning liquid SPM is approximately -30°C. The cleaning liquid SPM is an example of the second liquid.

A feeder 242 is connected to an end portion of the nozzle 240a opposite to a side facing the substrate 10 by a pipe 241a. The feeder 242 feeds the cleaning liquid SPM on the basis of an instruction of the electric controller 250. The cleaning liquid SPM fed from the feeder 242 is ejected from a leading end portion of the nozzle 240a through a pipe (not illustrated) passing through the nozzle 240a.

Note that although the pure water DI is used as the first liquid and the cleaning liquid SPM is used as the second liquid in the present embodiment, this is not restrictive. For example, instead of the pure water DI described above, any liquid may be used as long as a magnitude relationship between a dispersive component and a polar component of the liquid is equal to that in the exposure region ExR. As the second liquid, for example, a liquid containing sulfuric acid different from the above cleaning liquid SPM may be used. Alternatively, an organic solvent may be used as the second liquid.

The gas feeder 220 feeds cooling gas to a lower surface 104 of the substrate 10 placed on the stage 210 through a gas feed pipe 221 provided in a lower portion of the stage 210. The cooling gas is, for example, nitrogen (N₂) gas. A temperature of the cooling gas is approximately -25°C. By feeding the cooling gas from the lower surface 104 side, the substrate 10 is cooled to a temperature close to the temperature of the cooling gas.

The electric controller 250 is a computer including a central processing unit (CPU), a read only memory (ROM), and a random-access memory (RAM), each of which is not illustrated. The electric controller 250 performs the process for removing the adhesive residue 114g on the basis of a program and the like stored in the ROM or the like. The processing for removing the adhesive residue 114g is an example of substrate processing. To perform the substrate processing, the electric controller 250 controls the units of the substrate processing device 20 including the stage 210, the nozzle 230a, the nozzle 240a, the feeder 232, the feeder 242, and the gas feeder 220.

That is, in the substrate processing, the electric controller 250 controls the nozzle 230a and the feeder 232 to feed the pure water DI to the exposure region ExR of the substrate 10 placed on the stage 210 and thus form a liquid film. Furthermore, the electric controller 250 controls the gas feeder 220 to cool the substrate 10 and thus freeze the liquid film of the pure water DI that covers the exposure region ExR. Furthermore, the electric controller 250 controls the nozzle 240a and the feeder 242 to feed the cleaning liquid SPM to the frame region FR of the substrate 10 having its exposure region ExR covered with the frozen liquid film and thus remove the adhesive residue 114g attached to the frame region FR.

In general, wettability of a solid to a liquid is decided by a magnitude relationship between a dispersive component and a polar component in surface free energy of each of the solid and the liquid. More specifically, wettability of a solid to a liquid is decided by a ratio between a dispersive component and a polar component in surface free energy of each of the solid and the liquid.

The dispersive component is a component that constitutes surface free energy and is, for example, a component that arises from force generated by instantaneous electrical charge imbalance occurring between molecules. The polar component is a component that constitutes surface free energy and is, for example, a component that arises from force generated by instantaneous electrical charge imbalance occurring between polar molecules. In general, the polar component reflects a polar group density of a surface.

In a case where a magnitude relationship between a dispersive component and a polar component of a predetermined solid is identical to that of a predetermined liquid, the solid is easily wettable by the liquid. On the other hand, in a case where a magnitude relationship between a dispersive component and a polar component of a predetermined solid is different from that of a predetermined liquid, the solid is not easily wettable by the liquid.

In general, a ratio of a dispersive component is higher than that of a polar component in an organic substance or the like. On the other hand, in some organic substances such as water or relatively-low-molecular alcohol having a hydrophilic group, a ratio of a polar component is higher than that of a dispersive component. It can therefore be said that a substance having a magnitude relationship "dispersive component > polar component" tends to be hydrophobic, and a substance having a magnitude relationship "dispersive component < polar component" tends to be hydrophilic.

In the example of FIGS. 2A and 2B, the adhesive residue 114g attached to the frame region FR is an organic substance such as a SEBS resin or an acrylic resin. Accordingly, a magnitude relationship between a dispersive component and a polar component in the frame region FR is "dispersive component > polar component".

On the other hand, the exposure region ExR has been modified to have a polar group such as OH on a surface by an oxygen radical or the like generated by the UV treatment. Accordingly, a magnitude relationship between a dispersive component and a polar component in the exposure region ExR is "dispersive component < polar component".

That is, the frame region FR and the exposure region ExR are different in magnitude relationship between a dispersive component and a polar component in surface free energy. More specifically, the frame region FR and the exposure region ExR are different in ratio between a dispersive component and a polar component in surface free energy.

Furthermore, the outer edge region ER has been modified to have a polar group such as OH on a surface by an oxygen radical or the like generated by the UV treatment, as with the exposure region ExR. Accordingly, a magnitude relationship between a dispersive component and a polar component in the outer edge region ER is "dispersive component < polar component", as with the exposure region ExR.

That is, the frame region FR and the outer edge region ER are different in magnitude relationship between a dispersive component and a polar component in surface free energy. More specifically, the frame region FR and the outer edge region ER are different in ratio between a dispersive component and a polar component in surface free energy.

A magnitude relationship between a dispersive component and a polar component in water is "dispersive component < polar component". That is, the magnitude relationship between a dispersive component and a polar component in water is identical to that in the exposure region ExR. That is, the exposure region ExR has a tendency to be wetted by water (hydrophilic). On the other hand, the magnitude relationship between a dispersive component and a polar component in water is different from that in the frame region FR. That is, the frame region FR has a tendency to resist being wetted by water (hydrophobic).

In other words, the ratio between a dispersive component and a polar component in water is closer to the ratio between a dispersive component and a polar component in the exposure region ExR than to the ratio between a dispersive component and a polar component in the frame region FR.

Note that a value of surface free energy, which is a sum of a dispersive component and a polar component, is, for example, 30 N/m to 45 N/m in the frame region FR. A value of surface free energy is 70 mN/m to 100 mN/m in the exposure region ExR.

From above, the pure water DI fed to the exposure region ExR having a hydrophilic property forms a liquid film in a self-aligned manner inside the frame region FR having a hydrophobic property, that is, in the exposure region ExR. By freezing the liquid film thus formed, the exposure region ExR can be selectively covered with the freezing film. As a result, the exposure region ExR can be protected from the cleaning liquid SPM fed to the frame region FR to remove the adhesive residue 114g.

The substrate processing method according to the present embodiment is described in more detail below.

### Substrate Processing Method

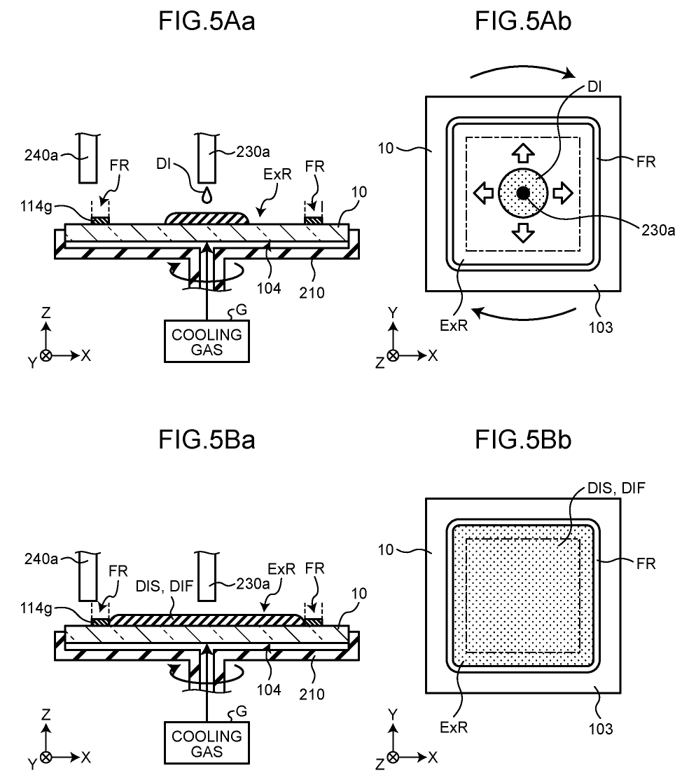

FIGS. 5Aa to 6Db illustrate part of a flow of the substrate processing according to the first embodiment in order. More specifically, FIGS. 5Aa to 6Da are each an XZ cross-sectional view of the substrate processing device 20 in a state where the substrate 10 is placed on the stage 210. FIGS. 5Ab to 6Db are each a top view of the substrate 10 placed on the stage 210 viewed from the positive side of the Z direction.

In FIGS. 5Ab to 6Db, a part of the nozzle 230a or the nozzle 240a is sometimes illustrated over the substrate 10. In FIGS. 5Aa to 6Da, in consideration of visibility, hatching is omitted, and illustration of some constituent elements such as the feeders 232 and 242 is omitted.

Prior to the process of FIGS. 5Aa and 5Ab, the upper surface 103 of the substrate 10 is UV treated. As a result, the exposure region ExR and the outer edge region ER of the upper surface 103 of the substrate 10 have a hydrophilic property.

As a first process, the electric controller 250 forms a liquid film DIS by feeding the pure water DI to the exposure region ExR.

Specifically, as illustrated in FIG. 5Aa, the electric controller 250 controls the nozzle 230a and the feeder 232 to eject the pure water DI of a predetermined amount to the exposure region ExR. During this process, the electric controller 250 causes the stage 210 to be rotated along the XY plane. As a result, as illustrated in FIG. 5Ab, the substrate 10 rotates along the XY plane, and the pure water DI ejected to the exposure region ExR spreads toward an outside of the substrate 10 on the upper surface 103.

The pure water DI that spreads in the exposure region ExR is stopped by the frame region FR that surrounds the exposure region ExR. This is because it is not easy for the pure water DI to spreads beyond the frame region FR due to the hydrophobic property of the frame region FR.

The pure water DI stopped by the frame region FR forms the liquid film DIS in a self-aligned manner inside the frame region FR, that is, in the exposure region ExR. The liquid film DIS is formed over the entire exposure region ExR. That is, the liquid film DIS is formed in a region that substantially matches the exposure region ExR when viewed from above.

Next, as a second process, the electric controller 250 solidifies the liquid film DIS formed in the exposure region ExR.

Specifically, in FIG. 5Aa, the electric controller 250 controls the gas feeder 220 to feed the cooling gas G to the lower surface 104 of the substrate 10 while the pure water DI is being ejected from the nozzle 230a. This freezes the liquid film DIS and thus forms an ice film DIF, as illustrated in FIGS. 5Ba and 5Bb. This is because the temperature of the cooling gas G is lower than the freezing point of the pure water DI. The exposure region ExR is thus covered with the ice film DIF.

However, a timing at which the cooling gas G is fed is not limited to the above example. For example, the electric controller 250 may start feed of the cooling gas G before the pure water DI is ejected from the nozzle 230a. By cooling the substrate 10 in advance, it is possible to shorten a period it takes to form the ice film DIF.

Next, as a third process, the electric controller 250 feeds the cleaning liquid SPM to the frame region FR.

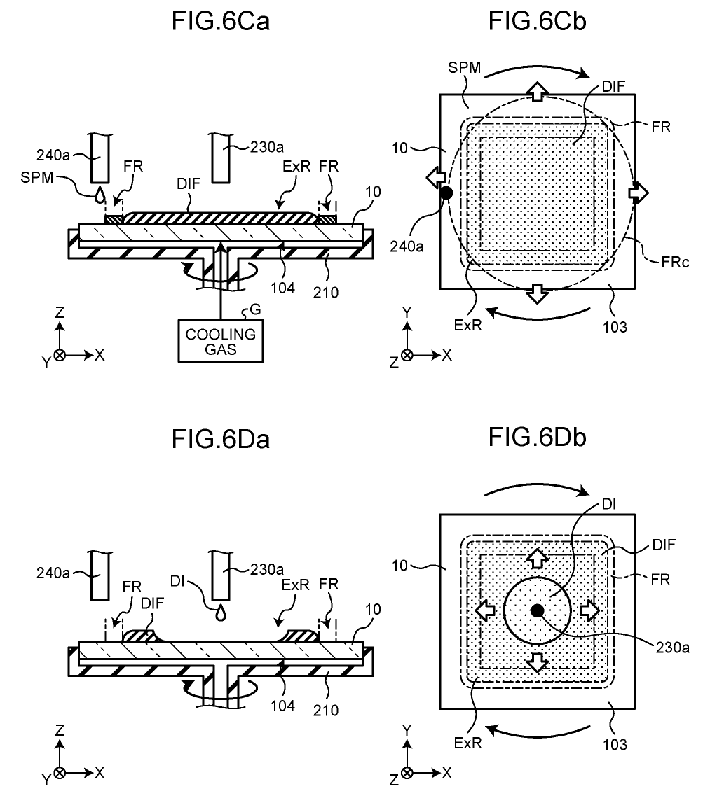

Specifically, as illustrated in FIG. 6Ca, the electric controller 250 controls the nozzle 240a and the feeder 242 to eject the cleaning liquid SPM from the nozzle 240a. The electric controller 250 causes the stage 210 to be rotated along the XY plane. As a result, as illustrated in FIG. 6Cb, the substrate 10 rotates along the XY plane, and the cleaning liquid SPM is fed along a circumference of a circle FRc (e.g., a circle inscribed in a peripheral edge portion of the upper surface 103) passing an end portion of the upper surface 103 of the substrate 10.

As described above, the cleaning liquid SPM ejected from the nozzle 240a spreads slightly inward from a landing point directly below the nozzle 240a after landing on the upper surface 103 of the substrate 10. That is, the cleaning liquid SPM spreads slightly inward of the circumference of the circle FRc. Furthermore, since the substrate 10 rotates along the XY plane, the cleaning liquid SPM spreads outward from the circumference of the circle FRc. Since the cleaning liquid SPM thus spreads outward from a position slightly inward of the circumference of the circle FRc, the cleaning liquid SPM is fed to the whole frame region FR, and the adhesive residue 114g attached to the frame region FR is dissolved. The cleaning liquid SPM that has dissolved the adhesive residue 114g is discharged from the end portion of the substrate 10 to an outside of the substrate 10.

In the third process, the electric controller 250 continues feed of the cooling gas G while the nozzle 240a is ejecting the cleaning liquid SPM. Since the substrate 10 is continuously cooled while the cleaning liquid SPM is being ejected, melting of the ice film DIF can be suppressed.

Note that the freezing point of the cleaning liquid SPM is lower than the temperature of the cooling gas G. Accordingly, the cleaning liquid SPM is not frozen.

Note that the electric controller 250 adjusts a rotational speed of the stage 210 during ejection of the cleaning liquid SPM from the nozzle 240a. Furthermore, the electric controller 250 adjusts a flow rate of the cleaning liquid SPM. For example, it is possible to keep the cleaning liquid SPM from entering too much the exposure region ExR inside the circle FRc by increasing the rotational speed of the stage 210 or reducing the flow rate of the cleaning liquid SPM. Accordingly, for example, even in a case where a part of the ice film DIF melts, a situation where the exposure region ExR and the pattern P are exposed to the cleaning liquid SPM due to infiltration or the like of the cleaning liquid SPM through the melted part can be avoided.

In the third process, after the adhesive residue 114g in the frame region FR is removed, the electric controller 250 stops feed of the cooling gas G. As a result, the temperature of the substrate 10 rises to approximately an ambient temperature.

Next, as illustrated in FIGS. 6Da and 6Db, the electric controller 250 controls the nozzle 230a and the feeder 232 to eject the pure water DI to the exposure region ExR. In this process, the electric controller 250 causes the stage 210 to be rotated along the XY plane. As a result, the pure water DI spreads toward the outside of the substrate 10 on the upper surface 103. This melts the ice film DIF and rinses the entire upper surface 103. Then, the ejection of the pure water DI is stopped, and the upper surface 103 is dried. The substrate processing according to the first embodiment thus ends.

### Overview

If an exposure region of a substrate of the photomask M is exposed to the cleaning liquid SPM in a process for removing an adhesive residue attached to the substrate, sulfate ions sometimes remain in the exposure region. If sulfate ions remain in the exposure region, the sulfate ions and nitrogen-induced ammonium ions or the like contained in an environment in which the photomask is used react due to exposure light, and a growing defect containing ammonium sulfate or the like is sometimes generated on a pattern of the photomask. Therefore, there are demands for removing the adhesive residue without exposing the exposure region to the cleaning liquid SPM.

In the substrate processing method according to the first embodiment, the ice film DIF is formed by solidifying the liquid film DIS, and thus the exposure region ExR is protected. This can suppress exposure of the exposure region ExR to the cleaning liquid SPM. As a result, occurrence of a growing defect or the like in the exposure region ExR can be suppressed.

Furthermore, since the exposure region ExR is protected by the ice film DIF, it is possible to keep dust or the like occurring when the adhesive residue 114g dissolves in the cleaning liquid SPM from being attached to the exposure region ExR.

As described above, according to the substrate processing method according to the first embodiment, the process for removing the adhesive residue 114g can be performed while suppressing occurrence of a growing defect in the substrate 10.

### First Modification of First Embodiment

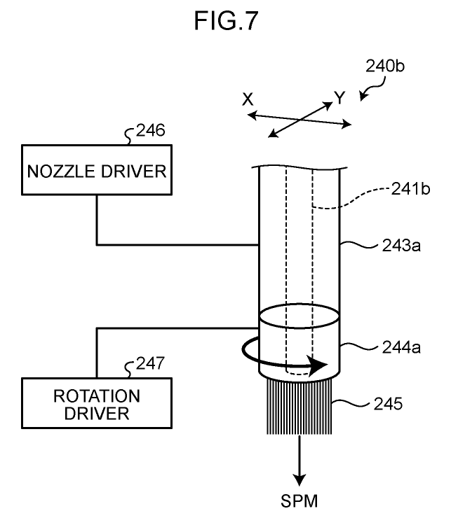

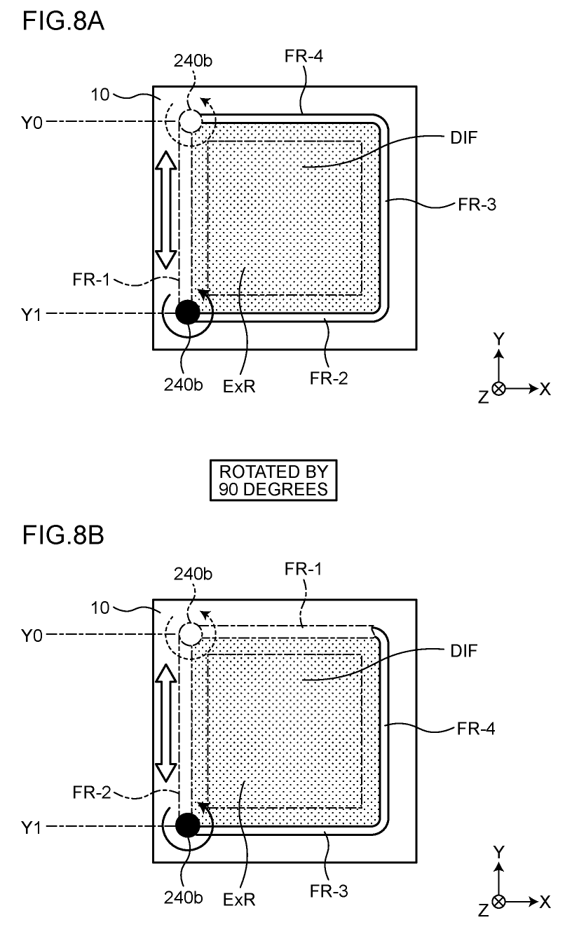

A substrate processing device and a substrate processing method according to a first modification of the first embodiment is described below with reference to FIGS. 7 and 8. According to the substrate processing device and the substrate processing method according to the first modification, physical action is applied to the adhesive residue 114g in addition to feed of the cleaning liquid SPM.

According to the substrate processing device and the substrate processing method according to the first embodiment described above, the cleaning liquid SPM is fed to the whole frame region FR by rotating the substrate 10 with respect to the nozzle 240a located at a predetermined position. On the other hand, according to the substrate processing device and the substrate processing method according to the first modification of the first embodiment, the cleaning liquid SPM is fed to the frame region FR while a nozzle 240b is moved along the frame region FR to apply physical action to the adhesive residue 114g. In the following description, constituent elements similar to those in the above first embodiment are given similar reference signs, and description thereof is sometimes omitted.

FIG. 7 is a diagram illustrating an example of a configuration of the nozzle 240b according to the first modification of the first embodiment.

As illustrated in FIG. 7, the nozzle 240b includes a body 243a extending in the up-down direction, a rotor 244a connected to a lower end of the body 243a, and a pipe 241b passing through the body 243a. An upper end portion of the pipe 241b in the body 243a is connected to the pipe 241a (see FIG. 4) described above extending from the feeder 242 that feeds the cleaning liquid SPM. The cleaning liquid SPM is ejected from a lower end portion of the rotor 244a through the pipe 241b passing through the body 243a.

The body 243a is movable in the X direction or the Y direction. Specifically, a nozzle driver 246 is connected to the body 243a. The nozzle driver 246 is an actuator including a motor (not illustrated). The nozzle driver 246 moves the body 243a in the X direction or the Y direction in accordance with an instruction from the electric controller 250.

The rotor 244a is rotatable along the XY plane. Specifically, a rotation driver 247 is connected to the rotor 244a. The rotation driver 247 is an actuator including a motor (not illustrated). The rotation driver 247 rotates the rotor 244a along the XY plane in accordance with an instruction from the electric controller 250.

A brush 245 contains synthetic fibers such as nylon or polyester. A lower end portion of the brush 245 makes contact with the upper surface 103 (see FIG. 4) of the substrate 10. As the rotor 244a rotates, the brush 245 also rotates along the XY plane.

FIGS. 8A and 8B illustrate part of a flow of substrate processing according to the first modification of the first embodiment in order.

FIGS. 8A and 8B are each a top view of the substrate 10 placed on the stage 210 viewed from the positive side of the Z direction. In FIGS. 8A and 8B, a part of the configuration of the nozzle 240b is illustrated over the substrate 10.

In the example of FIGS. 8A and 8B, the nozzle 240b moves in the Y direction. For example, the nozzle driver 246 moves the nozzle 240b in the Y direction from a standby position Y0 to an end position Y1 in accordance with an instruction from the electric controller 250. However, a direction in which the nozzle 240b moves is not limited to this. The nozzle 240b may move in the X direction.

In the substrate processing according to the first modification of the first embodiment, the processes in FIGS. 5Aa to 5Bb are performed prior to the process in FIG. 8A. As a result of the processes in FIGS. 5Ba and 5Bb, the exposure region ExR is covered with the ice film DIF.

As illustrated in FIG. 8A, the electric controller 250 controls the nozzle driver 246 to move the nozzle 240b to a position (the standby position Y0) that overlaps one end portion of a region FR-1, which is one side of the frame region FR having four sides.

When the nozzle 240b moves to the standby position Y0, the electric controller 250 causes the cleaning liquid SPM to be ejected from the nozzle 240b. In this process, the electric controller 250 controls the rotation driver 247 to rotate the rotor 244a of the nozzle 240b along the XY plane. As a result, the brush 245 starts to rotate, and physical action is applied to the adhesive residue 114g attached to the region FR-1. Since not only chemical action produced by the cleaning liquid SPM, but also physical action is applied to the adhesive residue 114g, the adhesive residue 114g can be efficiently removed.

Next, the electric controller 250 controls the nozzle driver 246 to move the nozzle 240b back and forth between the standby position Y0 and a position (the end portion Y1) that overlaps the other end portion of the region FR-1. In this process, the substrate 10 is kept stationary without rotation. The nozzle 240b moves back and forth at least one time or plural times between the standby position Y0 and the end position Y1. The adhesive residue 114g attached to the region FR-1 is thus removed.

As described above, the exposure region ExR is covered with the ice film DIF. Therefore, breakage or the like of the pattern P can be suppressed even in a case where physical action is applied to the substrate 10 by the brush 245.

Next, when the nozzle 240b returns to the standby position Y0, the electric controller 250 causes the substrate 10 to be rotated by 90 degrees in clockwise direction along the XY plane, as illustrated in FIG. 8B. As a result, the nozzle 240b overlaps, in the up-down direction, one end portion of a region FR-2 adjacent to the region FR-1. The one end portion of the region FR-2 is also the other end portion of the region FR-1.

Next, the electric controller 250 causes the cleaning liquid SPM to be ejected from the nozzle 240b and causes the brush 245 to be rotated. Then, the electric controller 250 causes the nozzle 240b to move back and forth one or more times between the standby position Y0 and the end position Y1. The adhesive residue 114g attached to the region FR-2 is thus removed.

Thereafter, the electric controller 250 repeats operation corresponding to the above operation on a region FR-3 and a region FR-4, and the adhesive residue 114g attached to the region FR-3 and the adhesive residue 114g attached to the region FR-4 are thus removed.

After the adhesive residue 114g attached to the regions FR-1 to FR-4 is removed, a process corresponding to the process in FIGS. 6Da and 6Db is performed. The substrate processing according to the first modification thus ends.

According to the substrate processing device and the substrate processing method according to the first modification of the first embodiment, the adhesive residue 114g can be removed in a shorter time with more certainty by applying physical action to the adhesive residue 114g in addition to feed of the cleaning liquid SPM.

According to the substrate processing device and the substrate processing method according to the first modification of the first embodiment, effects similar to those of the substrate processing device and the substrate processing method according to the above first embodiment are also produced.

### Second Modification of First Embodiment

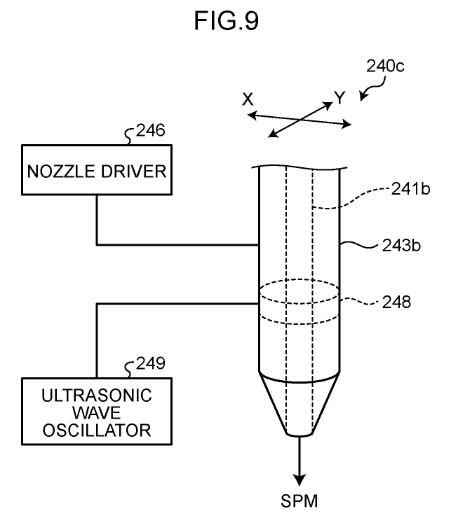

A substrate processing device according to a second modification of the first embodiment is described below with reference to FIG. 9. Also, according to the substrate processing device according to the second modification, physical action is applied to the adhesive residue 114g in addition to feed of the cleaning liquid SPM. However, according to the substrate processing device according to the second modification, physical action is applied to the adhesive residue 114g by a nozzle 240c having a configuration different from that of the above first modification by a method different from that of the above first modification. In the following description, constituent elements similar to those in the above first modification are given similar reference signs, and description thereof is sometimes omitted.

FIG. 9 is a diagram illustrating an example of a configuration of the nozzle 240c according to the second modification of the first embodiment.

As illustrated in FIG. 9, the nozzle 240c includes a body 243b extending in the up-down direction, a transducer 248 provided inside the body 243b, and a pipe 241b passing through the body 243b. The cleaning liquid SPM is ejected from a lower end portion of the body 243b through the pipe 241a passing through the body 243b.

An ultrasonic wave transducer 249 is connected to the transducer 248. The transducer 248 generates an ultrasonic wave based on an electric signal supplied from the ultrasonic wave oscillator 249 and propagates the ultrasonic wave into the cleaning liquid SPM fed through the pipes 241a and 241b. By oscillating the cleaning liquid SPM in a molecular level by using the ultrasonic wave, physical action is applied to the adhesive residue 114g attached to the frame region FR.

According to the substrate processing device according to the first modification, effects similar to those of the substrate processing device according to the above first modification are produced.

### Third Modification of First Embodiment

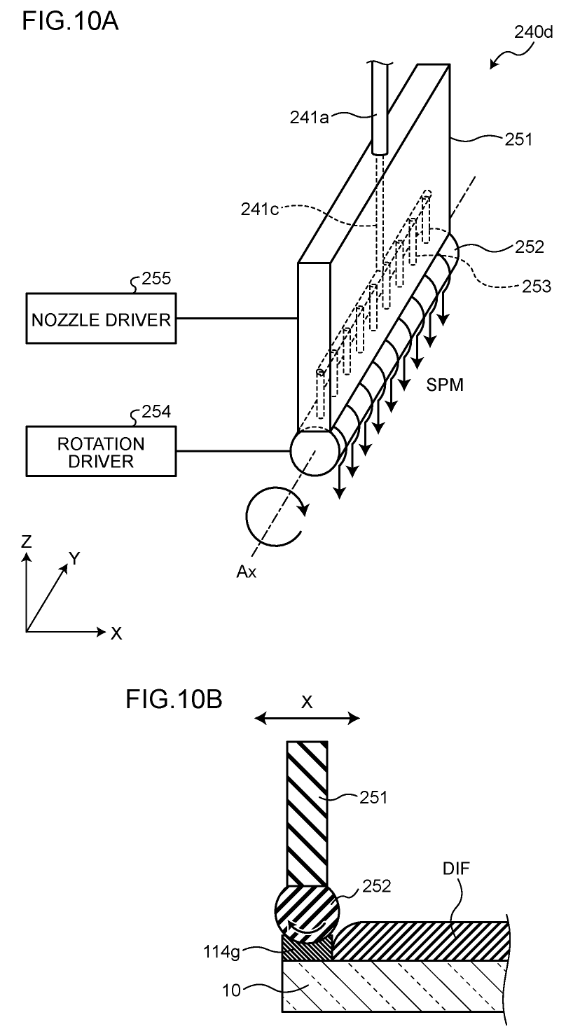

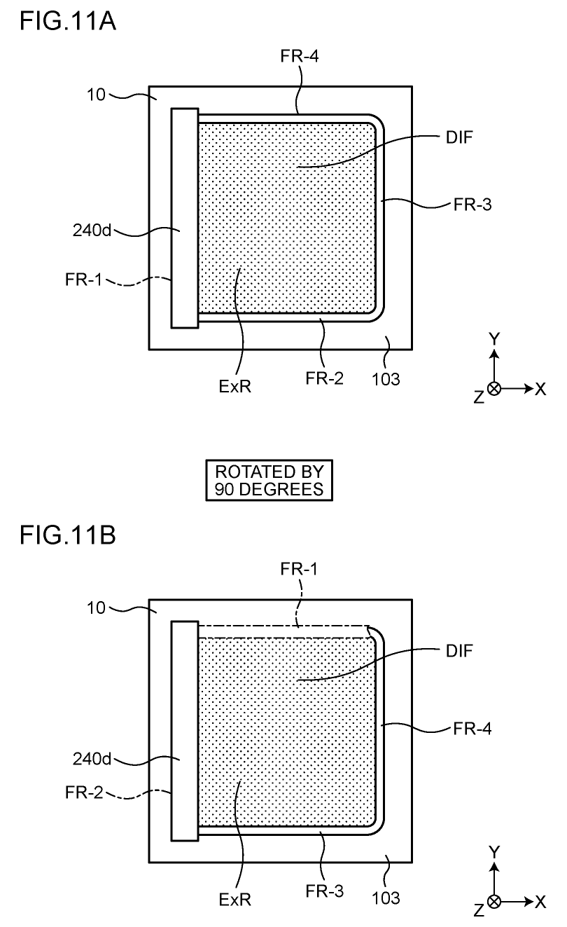

A substrate processing device and a substrate processing method according to a third modification of the first embodiment are described below with reference to FIGS. 10A to 11B. The substrate processing device and the substrate processing method according to the third modification are different from those of the above first embodiment in configuration of a nozzle 240d. In the following description, constituent elements similar to those in the above first embodiment are given similar reference signs, and description thereof is sometimes omitted.

FIGS. 10A and 10B are diagrams illustrating an example of a configuration of the nozzle 240d according to the third modification of the first embodiment.

As illustrated in FIG. 10A, the nozzle 240d includes an extender 251 extending in the Y direction, a roller 252 connected to a lower end portion of the extender 251, a pipe 241c passing through the extender 251, and a plurality of ejection ports 253 into which the pipe 241c branches. The nozzle 240d is an example of a second nozzle. An upper end portion of the pipe 241c inside the extender 251 is connected to the pipe 241a (see FIG. 4) described above extending from the feeder 242 that feeds the cleaning liquid SPM.

The pipe 241c passing through the extender 251 branches in the Y direction before the roller 252 and is connected to the plurality of ejection ports 253 on a lower surface of the extender 251. The plurality of ejection ports 253 are spaced part from one another by a predetermined distance in the Y direction. The cleaning liquid SPM is ejected from the ejection ports 253 through the pipe 241c.

The extender 251 is movable in the X direction. Specifically, a nozzle driver 255 is connected to the extender 251. The nozzle driver 255 is an actuator including a motor (not illustrated). The nozzle driver 255 moves the extender 251 in the X direction in accordance with an instruction from the electric controller 250. However, a direction in which the extender 251 moves is not limited to this. For example, in a case where the extender 251 extends in the X direction, the extender 251 moves in the Y direction.

The roller 252 is provided on a lower end portion of the extender 251 as described above, and a lower end portion of the roller 252 is in contact with the upper surface 103 (see FIG. 4) of the substrate 10. The roller 252 extends in the Y direction and is rotatable toward the outside of the substrate 10 about a rotary axis Ax extending in the extending direction of the roller 252 (FIG. 10B).

Specifically, a rotation driver 254 is connected to the roller 252. The rotation driver 254 is an actuator including a motor (not illustrated). The rotation driver 254 rotates the roller 252 in accordance with an instruction from the electric controller 250. According to the above configuration, the nozzle 240d is movable in the X direction while the roller 252 is rotated.

FIGS. 11A and 11B illustrate part of a flow of substrate processing according to the third modification of the first embodiment in order.

FIGS. 11A and 11B are each a top view of the substrate 10 placed on the stage 210 viewed from the positive side in the Z direction. In FIGS. 11A and 11B, a part of the nozzle 240d is illustrated over the substrate 10.

In the example of FIGS. 11A and 11B, the nozzle 240d extends in the Y direction at a position on the left side of the paper, that is, on the negative side in the X direction. The nozzle 240d is located so as to overlap the region FR-1 of the substrate 10 placed on the stage 210.

However, the direction in which the nozzle 240d extends is not limited to this. For example, the nozzle 240d may extend in the Y direction at a position on the right side of the paper, that is, on the positive side in the X direction. Alternatively, for example, the nozzle 240d may extend in the X direction at a position on the upper side or the lower side of the paper.

In the substrate processing according to the third modification, the processes in FIGS. 5Aa to 5Bb are performed prior to the process in FIG. 11A. As a result of the processes in FIGS. 5Ba and 5Bb, the exposure region ExR is covered with the ice film DIF.

As illustrated in FIG. 11A, the electric controller 250 causes the cleaning liquid SPM to be ejected from the nozzle 240d at a position that overlaps the region FR-1. Furthermore, the electric controller 250 controls the rotation driver 254 to rotate the roller 252 so that the lower end portion of the roller 252 that is in contact with the substrate 10 moves toward the outside of the substrate 10. Furthermore, the electric controller 250 controls the nozzle driver 255 to move the extender 251 in the X direction toward the outside of the substrate 10. The electric controller 250 keeps the stage 210 stationary without rotating the stage 210.

Since the extender 251 moves to the outside of the substrate 10 and the roller 252 provided on the lower end portion of the extender 251 rotates toward the outside of the substrate 10, physical action is applied to the adhesive residue 114g attached to the region FR-1. The cleaning liquid SPM that has dissolved the adhesive residue 114g is thus discharged to the outside of the substrate 10. As a result, infiltration of the cleaning liquid SPM into an inside of the exposure region ExR can be suppressed.

As described above, the nozzle 240d extends in the Y direction. Therefore, the adhesive residue 114g attached to the region FR-1 can be collectively removed. This can shorten a processing period.

Since the processing period can be shortened, a risk of melting of a part of the ice film DIF can be reduced, and therefore exposure of the exposure region ExR to the cleaning liquid SPM can be avoided.

After the adhesive residue 114g attached to the region FR-1 is removed, the electric controller 250 causes the substrate 10 to be rotated by 90 degrees along the XY plane in clockwise direction, as illustrated in FIG. 11B. As a result, the nozzle 240d overlaps, in the up-down direction, the region FR-2 adjacent to the region FR-1.

Next, the electric controller 250 causes the cleaning liquid SPM to be ejected from the nozzle 240d and causes the roller 252 to be rotated while moving the extender 251 toward the outside of the substrate 10.

Thereafter, the electric controller 250 repeats operation corresponding to the above operation on the region FR-3 and the region FR-4, and thus the adhesive residue 114g attached to the region FR-3 and the adhesive residue 114g attached to the region FR-4 are sequentially removed.

After the adhesive residue 114g attached to the regions FR-1 to FR-4 is removed, the process corresponding to the process of FIGS. 6Da and 6Db is performed. The substrate processing according to the third modification thus ends.

According to the substrate processing device and the substrate processing method according to the third modification, the nozzle 240d extends in the Y direction, and therefore the adhesive residue 114g attached to one side of the frame region FR can be collectively removed, and the processing period can be shortened.

According to the substrate processing device and the substrate processing method according to the third modification, the roller 252 rotates toward the outside of the substrate 10. The cleaning liquid SPM that has dissolved the adhesive residue 114g is thus discharged to the outside of the substrate 10, and infiltration of the cleaning liquid SPM into the inside of the exposure region ExR can be suppressed.

According to the substrate processing device and the substrate processing method according to the third modification, effects similar to those produced by the above first embodiment and the modifications are also produced.

### Second Embodiment

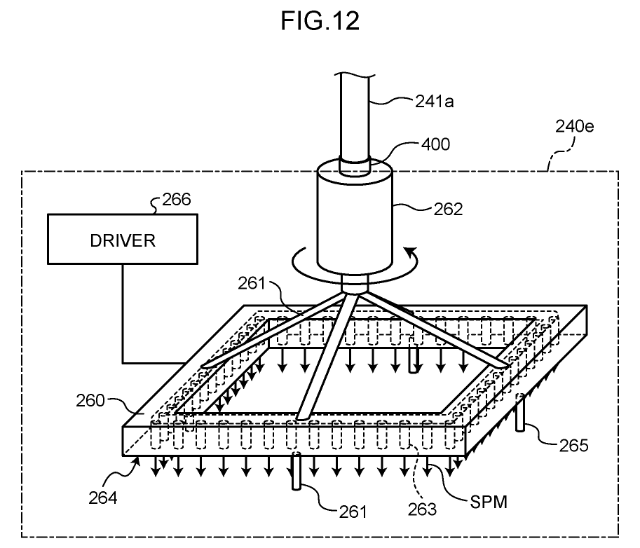

A second embodiment is described below with reference to FIGS. 12 to 14. A substrate processing device according to the second embodiment is different from that of the above first embodiment in configuration and operation of a nozzle 240e. In the following description, constituent elements similar to those in the above first embodiment are given similar reference signs, and description thereof is sometimes omitted.

### Example of Configuration of Nozzle

FIG. 12 is a diagram illustrating an example of a configuration of the nozzle 240e according to the second embodiment. The nozzle 240e is an example of a second nozzle.

As illustrated in FIG. 12, the nozzle 240e includes a nozzle head 260 having a frame shape, a support portion 261 that supports the nozzle head 260 from an upper side, and a buffer tank 262.

The buffer tank 262 stores therein a cleaning liquid SPM fed through a pipe 241a and feeds the cleaning liquid SPM of a necessary amount to the nozzle head 260 in accordance with an instruction from an electric controller 250. An upper end portion of the buffer tank 262 is connected to the pipe 241a extending from a feeder 242 (see FIG. 4) that feeds the cleaning liquid SPM, and a lower end portion of the buffer tank 262 is connected to an upper end portion of the support portion 261.

For example, four support portions 261 are connected to the lower end portion of the buffer tank 262. End portions of the four support portions 261 opposite to ends connected to the buffer tank 262 are connected to the nozzle head 260. The cleaning liquid SPM fed from the buffer tank 262 is fed to the nozzle head 260 by passing through the four support portions 261.

A plurality of ejection ports 263 are provided on a lower surface 264 of the nozzle head 260. That is, the plurality of ejection ports 263 are arranged in a frame shape along the lower surface 264 of the nozzle head 260. The cleaning liquid SPM fed from the buffer tank 262 through the four support portions 261 is ejected from the plurality of ejection ports 263.

Furthermore, a plurality of pins 265 protrude from the lower surface 264 of the nozzle head 260. The plurality of pins 265 are connectable to a stage 210. A manner of connection between the plurality of pins 265 and the stage 210 will be described later in detail. The nozzle 240e is rotatable along the XY plane in synchronization with rotation of the stage 210 in a state where the nozzle head 260 and the stage 210 are connected.

A rotary joint 400 that is rotatable along the XY plane is provided at a portion where the buffer tank 262 and the pipe 241a are connected. The nozzle 240e including the buffer tank 262 is thus rotatable along the XY plane without being tangled with the pipe 241a.

When the nozzle 240e rotates along the XY plane, the cleaning liquid SPM of a necessary amount is fed from the buffer tank 262 to the nozzle head 260. Therefore, the nozzle 240e can eject the cleaning liquid SPM while rotating along the XY plane.

Furthermore, a raising/lowering driver 266 is connected to the nozzle 240e. The raising/lowering driver 266 is an actuator including a motor (not illustrated). The raising/lowering driver 266 raises or lowers the nozzle 240e in accordance with an instruction from the electric controller 250. When the nozzle 240e is lowered from a standby position by the raising/lowering driver 266, the plurality of pins 265 are connected to connection portions of the stage 210, and the nozzle 240e becomes rotatable in synchronization with rotation of the stage 210. When the nozzle 240e is raised by the raising/lowering driver 266 in a state where the nozzle 240e is at a lowered position and the plurality of pins 265 and the stage 210 are connected, the plurality of pins 265 and the stage 210 are disconnected from each other.

### Substrate Processing Method

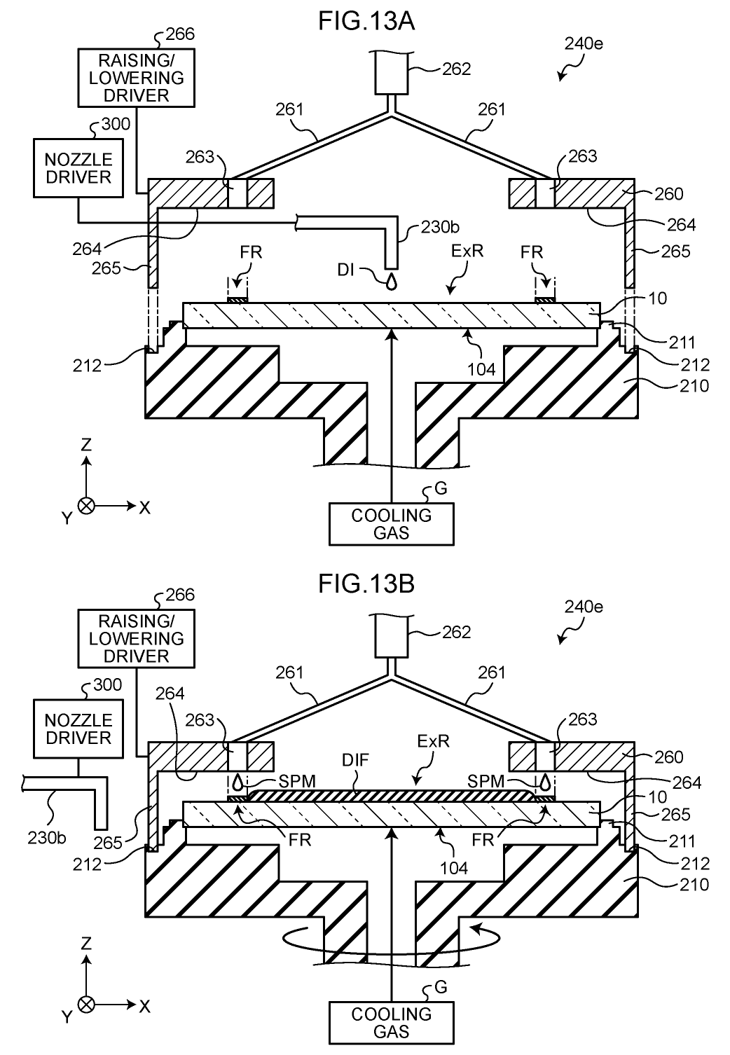

FIGS. 13A and 13B illustrate part of a flow of substrate processing according to the second embodiment in order. More specifically, FIGS. 13A and 13B are each an XZ cross-sectional view of a substrate processing device in a state where the substrate 10 is placed on the stage 210. In FIGS. 13A and 13B, a part of the configuration above the buffer tank 262 is omitted.

As illustrated in FIGS. 13A and 13B, in the substrate processing device according to the second embodiment, a nozzle driver 300 is connected to a nozzle 230b. The nozzle driver 300 is an actuator including a motor (not illustrated). The nozzle driver 300 moves the nozzle 230b in the X direction and the Y direction in accordance with an instruction from the electric controller 250. Specifically, the electric controller 250 controls the nozzle driver 300 to move the nozzle 230b to an ejection position above the exposure region ExR in a case where pure water DI is ejected from the nozzle 230b and controls the nozzle driver 300 to evacuate the nozzle 230b from the position above the exposure region ExR to a standby position in a case where the nozzle 230b is not used.

In the substrate processing device according to the second embodiment, the stage 210 has, on an outer edge portion, recessed portions 212 into which the plurality of pins 265 protruding from the lower surface 104 of the nozzle 240e can be fitted. When the nozzle 240e is lowered, and the plurality of pins 265 and the recessed portions 212 are fitted, the nozzle 240e and the stage 210 are connected.

In the X direction, a dimension of the nozzle head 260 is substantially equal to a dimension of the stage 210. Furthermore, the plurality of ejection ports 263 of the nozzle head 260 are located so as to overlap a frame region FR in the up-down direction.

Prior to the process in FIG. 13A, the nozzle 240e is in a raised position, which is the standby position. The nozzle 230b is at the standby position deviated from the position above the exposure region ExR. The electric controller 250 controls a robotic arm (not illustrated) to place the substrate 10 on a plurality of support pins 211 provided on an outer edge portion of the stage 210.

As illustrated in FIG. 13A, the electric controller 250 controls the nozzle driver 300 to move the nozzle 230b to a position above the exposure region ExR.

Next, the electric controller 250 causes the pure water DI to be ejected from the nozzle 230b. Furthermore, the electric controller 250 causes the stage 210 to be rotated. The pure water DI ejected to the exposure region ExR spreads toward an outside of the substrate 10. In this process, the electric controller 250 causes cooling gas G to be fed. This forms an ice film DIF that covers the exposure region ExR. After the ice film DIF is formed, the electric controller 250 stops feed of the pure water DI from the nozzle 230b and controls the nozzle driver 300 to evacuate the nozzle 230b to the outside of the stage 210.

Next, as illustrated in FIG. 13B, the electric controller 250 controls the raising/lowering driver 266 to lower the nozzle 240e. As a result, the plurality of pins 265 and the recessed portions 212 are fitted, and the nozzle 240e and the stage 210 are thus connected. Furthermore, the plurality of ejection ports 263 of the nozzle head 260 are located above the frame region FR in proximity with the frame region FR.

The electric controller 250 controls the buffer tank 262 to eject the cleaning liquid SPM from the plurality of ejection ports 263.

Furthermore, in this process, the electric controller 250 causes the stage 210 to be rotated along the XY plane. When the stage 210 is rotated, the substrate 10 and the nozzle 240e also rotate integrally with the stage 210 in synchronization with the rotation of the stage 210. This is because the stage 210 and the nozzle 240e are connected by the plurality of pins 265. A rotational speed of the stage 210 in this process is 50 rpm to 100 rpm. This allows the cleaning liquid SPM ejected from the plurality of ejection ports 263 to land on the frame region FR with more certainty, for example, without being influenced by centrifugal force.

By thus feeding the cleaning liquid SPM, an adhesive residue 114g attached to the frame region FR is dissolved. Furthermore, by rotating the substrate 10, the cleaning liquid SPM that has dissolved the adhesive residue 114g is discharged to the outside of the substrate 10. Therefore, exposure of the exposure region ExR to the cleaning liquid SPM can be avoided.

Since the plurality of ejection ports 263 are arranged in a frame shape along the lower surface 264 of the nozzle head 260, the adhesive residue 114g attached to the frame region FR can be collectively removed. This can shorten a processing period.

After the process of FIG. 13B, a process corresponding to the process of FIGS. 6Da and 6Db is performed. The substrate processing according to the second embodiment thus ends.

According to the substrate processing device and the substrate processing method according to the second embodiment, the nozzle head 260 has a frame shape, and therefore the cleaning liquid SPM can be fed collectively to the substantially entire frame region FR, and the adhesive residue 114g attached to the frame region FR can be collectively removed.

According to the substrate processing device and the substrate processing method according to the second embodiment, the nozzle head 260 is connected to the stage 210 and is rotated in synchronization with the stage 210 during cleaning using the cleaning liquid SPM. This can reduce positional deviation between the plurality of ejection ports 263 of the nozzle head 260 and the frame region FR, thereby making it possible to feed the cleaning liquid SPM from the nozzle head 260 to the frame region FR with more certainty. Therefore, the adhesive residue 114g attached to the frame region FR can be removed in a short time with more certainty.

According to the substrate processing device and the substrate processing method according to the second embodiment, effects similar to those of the substrate processing device and the substrate processing method according to the first embodiment are also produced.

### Modification of Second Embodiment

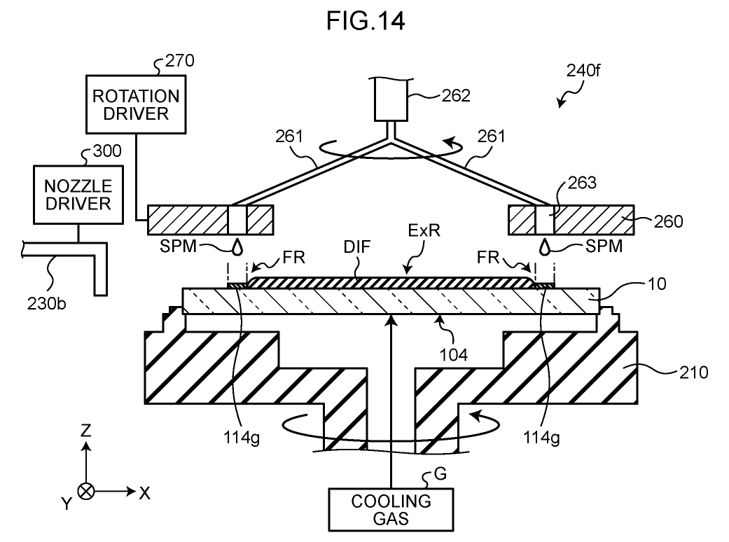

A substrate processing device according to a modification of the second embodiment is described below with reference to FIG. 14. In the substrate processing device according to the second embodiment described above, the stage 210 and the nozzle 240e are connected, and the stage 210 and the nozzle 240e rotate integrally. On the other hand, according to the substrate processing device according to the modification, the nozzle 240e and the stage 210 rotate independently. In the following description, constituent elements similar to those in the above second embodiment are given similar reference signs, and description thereof is sometimes omitted.

FIG. 14 is a diagram illustrating an example of a configuration of a nozzle 240f according to the modification of the second embodiment. More specifically, FIG. 14 is an XZ cross-sectional view of the substrate processing device in a state where the substrate 10 is placed on the stage 210. In FIG. 14, a part of the configuration above the buffer tank 262 is omitted.

As illustrated in FIG. 14, a rotation driver 270 is connected to the nozzle 240f. The rotation driver 270 is an actuator including a motor (not illustrated). The rotation driver 270 controls rotation of the nozzle head 260 along the XY plane in accordance with an instruction from the electric controller 250.

After the ice film DIF that covers the exposure region ExR is formed, the electric controller 250 controls the nozzle driver 300 to evacuate the nozzle 230b to the outside of the stage 210.

The electric controller 250 controls the buffer tank 262 to eject the cleaning liquid SPM from the plurality of ejection ports 263. The electric controller 250 causes the stage 210 to be rotated along the XY plane. Furthermore, the electric controller 250 controls the rotation driver 270 to rotate the nozzle head 260 in synchronization with the rotation of the stage 210. The stage 210, the substrate 10, and the nozzle 240e thus rotate in synchronization with one another.

According to the substrate processing device and the substrate processing method according to the modification, effects similar to those of the substrate processing device 20 and the substrate processing method according to the above second embodiment are produced.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A substrate processing method comprising:
a first process of forming a liquid film in a second region of a substrate having, on a first surface, a first region and the second region provided inside the first region by feeding a first liquid to the second region;
a second process of solidifying the liquid film; and
a third process of feeding a second liquid different from the first liquid to the first region of the substrate on which the liquid film has been solidified, wherein
the first region and the second region are different in magnitude relationship between a dispersive component and a polar component in surface free energy, and
a magnitude relationship between a dispersive component and a polar component in surface free energy of the first liquid is equal to the magnitude relationship in the second region.

2. The substrate processing method according to claim 1, wherein
the liquid film is formed over the entire second region.

3. The substrate processing method according to claim 1, wherein
the first region and the second region are provided inside a third region in which a ratio between a dispersive component and a dispersive component in surface free energy is different from the first region.

4. The substrate processing method according to claim 1, wherein
solidifying the liquid film in the second process is freezing the liquid film by feeding cooling gas to a second surface of the substrate opposite to the first surface.

5. The substrate processing method according to claim 4, wherein
feed of the cooling gas is continued when the second liquid is fed to the first region in the third process.

6. The substrate processing method according to claim 1, wherein
physical action using at least one of a brush and an ultrasonic wave is applied to the first region when the second liquid is fed to the first region in the third process.

7. The substrate processing method according to claim 1, wherein
the second liquid contains a sulfate ion.

8. The substrate processing method according to claim 1, wherein
the second liquid is an organic solvent.

9. The substrate processing method according to claim 1, wherein
the substrate is a substrate of a photomask, and
a component of an adhesive for bonding a pellicle for protecting the second region to the first region is attached to the first region.

10. A substrate processing device comprising:
a stage on which a substrate having, on a first surface, a first region and a second region provided inside the first region is placeable, the stage being capable of rotating the substrate in a substantially horizontal direction;
a first nozzle provided above the stage, the first nozzle being capable of feeding a first liquid to the second region of the substrate placed on the stage;
a second nozzle provided above the stage, the second nozzle being capable of feeding a second liquid different from the first liquid to the first region of the substrate placed on the stage;
a gas feeder that is capable of feeding cooling gas to a second surface of the substrate opposite to the first surface, the substrate being placed on the stage; and
an electric controller that controls the stage, the first nozzle, the second nozzle, and the gas feeder, wherein
the electric controller:
causes the first liquid to be ejected from the first nozzle to form a liquid film of the first liquid in the second region of the substrate;
causes the cooling gas to be fed from the gas feeder to solidify the liquid film; and
causes the second liquid to be ejected from the second nozzle to feed the second liquid to the first region of the substrate on which the liquid film has been solidified,
the first region and the second region are different in magnitude relationship between a dispersive component and a polar component in surface free energy, and
a magnitude relationship between a dispersive component and a polar component in surface free energy of the first liquid is equal to the magnitude relationship in the second region.

11. The substrate processing device according to claim 10, wherein
the second nozzle extends in a direction along the first surface at a position that overlaps at least a part of the first region of the substrate placed on the stage in top view.

12. The substrate processing device according to claim 10, wherein
the second nozzle includes a nozzle head having a frame shape, and
the nozzle head is located so as to overlap the first region of the substrate placed on the stage in top view.

13. The substrate processing device according to claim 12, wherein
the nozzle head is rotatable in a direction along the first surface of the substrate placed on the stage in synchronization with rotation of the stage.

14. The substrate processing device according to claim 13, wherein
the second nozzle:
is connected to the stage by a support pin at least when ejecting the second liquid; and
is rotatable in a direction along the first surface of the substrate placed on the stage as the stage rotates.

15. The substrate processing device according to claim 13, wherein
the second nozzle includes a driver that controls rotation action of the nozzle head based on an instruction from the electric controller, and
the electric controller controls the driver to rotate the nozzle head in synchronization with rotation of the stage.

16. The substrate processing device according to claim 10, wherein
the second nozzle includes: a body that extends in a direction crossing the first surface of the substrate and through which the second liquid passes; and a brush that is connected to an end portion of the body closer to the substrate and from which the second liquid is ejected, and
the brush makes contact with the first surface of the substrate and rotates along the first surface.

17. The substrate processing device according to claim 10, wherein
the second nozzle includes: a body that extends in a direction crossing the first surface of the substrate and through which the second liquid passes; and a transducer that is provided inside the body and is connected to an ultrasonic wave oscillator, and
the transducer generates an ultrasonic wave by an electric signal supplied from the ultrasonic wave oscillator and propagates the ultrasonic wave into the second liquid passing through the body.

18. The substrate processing device according to claim 11, wherein
the second nozzle includes: an extender that extends in a direction along the first surface of the substrate and through which the second liquid passes; and a roller that extends along the extender and is connected to a surface of the extender that is closer to the substrate and from which the second liquid is ejected, and
the roller makes contact with the first surface of the substrate and rotates in a direction toward an outside of the substrate about a rotary axis extending in a direction in which the roller extends.
